(19) United States
(12) Patent Application Publication
(10) Pub. No.: US 2007/0045695 A1
(43) Pub. Date: Mar. 1, 2007

(54) Method for fabricating semiconductor device and semiconductor device

(76) Inventors: Shinji Takeoka, Osaka (JP); Akio Sebe, Osaka (JP); Junji Hirase, Osaka (JP); Naoki Kotani, Hyogo (JP); Gen Okazaki, Hyogo (JP); Kazuhiko Aida, Chiba (JP)

Correspondence Address: MCDERMOTT WILL & EMERY LLP, 600 13TH STREET, N.W., WASHINGTON, DC, 20005-3096, US

(21) Appl. No.: 11/491,936

(22) Filed: Jul. 25, 2006

(30) Foreign Application Priority Data
Aug. 25, 2005 (JP) 2005-244252

(51) Int. Cl. H01L 29/94

(52) U.S. Cl. 257/296

(57) ABSTRACT

A Ni film is deposited over the entire surface of a substrate including a silicon gate. Then, the silicon gate is partially removed by, for example, CMP, thereby leaving a Ni layer having a flat upper surface and a uniform thickness directly on the silicon gate. Subsequently, silicidation is performed, thereby forming a gate electrode having a uniform silicide phase.

### BACKGROUND OF THE INVENTION

1. Field of the Invention

The present invention relates to methods for fabricating field-effect transistors using silicide gate electrodes, and particularly to methods for forming fully-silicided (FUSI) gate electrodes.

2. Description of the Related Art

With reduction in design rule of semiconductor devices, the circuit integration degree has rapidly increased, thus allowing a hundred million or more field-effect transistors (FETs) such as MOS transistors to be mounted on one chip. To implement such chips, not only progress of ultra-micro processing techniques such as development of lithography and etching with processing accuracy on the order of several tens of nanometers but also metallization of gate electrodes are demanded.

Polysilicon is conventionally used as a material for gate electrodes of MOS transistors. However, when semiconductor is used as a material for a gate electrode, a problem in which depletion is formed in the gate electrode to increase the thickness of an electrical gate oxide film arises. The “electrical gate oxide film” herein is a layer substantially serving as a gate oxide film as a result of depletion. In a generation with a gate length of about 90 nm, a required thickness of an electrical gate oxide film is 2.0 nm to 2.4 nm. The thickness of the electrical gate oxide film increases by about 0.3 nm as a result of depletion formed in the gate electrode, so that reduction of the thickness of the actual gate oxide film could cope with the problem. However, as the gate length is reduced to 65 nm and then to 45 nm, the required thickness of the electrical gate oxide film decreases. For example, in a generation with a gate length of 45 nm, the required thickness of the electrical gate oxide film is about 1.2 nm to 1.6 nm. If a gate electrode of polysilicon is used in such a generation, it is difficult to compensate for the increase in thickness of the electrical gate oxide film due to depletion in the gate electrode by using other techniques. In view of this, a new gate electrode material is needed.

In recent years, attention has been focused on a fully-silicided (FUSI) gate technique with which the entire polysilicon gate electrode is silicided with a metal such as Co or Ni as a technique for preventing depletion from being formed in a gate electrode (see Aoyama et al., IEDM Tech. Dig. pp. 95-98 (2004)). Techniques of siliciding only an upper portion of a polysilicon gate electrode with, for example, Co or Ni have been conventionally used in order to reduce the gate electrode resistance. Therefore, the FUSI gate technique is an extension of the conventional techniques and is a promising technique because a new material is not used.

### SUMMARY OF THE INVENTION

In the FUSI gate technique, however, a large amount of metal such as Ni is deposited on polysilicon to cause silicidation, so that the phase of resultant silicide changes according to the amount of supplied Ni, and transistor characteristics become unstable.

FIGS. 4A through 4C are cross-sectional views showing an example of a flow of conventional FUSI formation.

First, as illustrated in FIG. 4A, according to the flow of standard MOS transistor formation, a gate insulating film 1101 and a polysilicon layer 1102 are formed in this order on a semiconductor substrate 1100, and then extension implantation is performed. Subsequently, sidewalls 1103 made of an insulating film and source/drain regions are formed. Thereafter, an interlayer insulating film 1104 is deposited over the substrate. Then, the upper surface of the polysilicon layer 1102 is exposed by chemical mechanical polishing (CMP), and then the height of the polysilicon layer 1102 is adjusted using a chemical solution and a dry etching technique. Next, as illustrated in FIG. 4B, a Ni film 1105 is deposited over the entire surface of the substrate. Thereafter, as illustrated in FIG. 4C, heat treatment is performed on the substrate to form silicide. In this manner, the entire gate electrode is silicided.

In this case, as shown in FIG. 4C, portions of the gate electrode near the sidewalls and the middle portion of the gate electrode exhibit different silicide phases. Specifically, in the portions near the sidewalls where Ni is supplied from the interlayer insulating film, a large amount of Ni is supplied, so that a Ni₃Si layer 1106 is formed. In the middle portion where the amount of supplied Ni is determined by the thickness of the overlying Ni film, a NiSi layer 1107 is formed. Since Ni₃Si and NiSi have different work functions, characteristics of a transistor having such a structure are very unstable. In addition, part of the upper surface of the gate electrode after silicidation is not flat.

It is therefore an object of the present invention to provide a semiconductor device including a FUSI gate electrode having a uniform silicide phase and a method for fabricating the device.

### Means for Solving the Problems

To solve the conventional problems described above, according to the present invention, the amount of Ni supplied to polysilicon is controlled before silicidation of a gate electrode so as to make the FUSI gate electrode have a uniform silicide phase.

Specifically, a method for fabricating a semiconductor device according to the present invention includes the steps of: (a) forming a first silicon gate over a semiconductor substrate with a first gate insulating film interposed therebetween; (b) forming a first recess surrounded by an insulating film on the first silicon gate; (c) forming a metal film over the semiconductor substrate such that at least the first recess is filled with the metal film; (d) partially removing the metal film to expose the insulating film, thereby forming a first metal layer in the first recess on the first silicon gate; and (e) performing heat treatment to cause reaction between the first metal layer and the first silicon gate, thereby forming a first gate electrode made of a first metal silicide.

With this method, the redundant metal film is removed in the step (d) before silicidation of the gate electrode at the step (e), so that a uniform amount of metal is allowed to be supplied to the entire part of the gate electrode during silicidation. Accordingly, the gate electrode is made of metal silicide having a uniform composition, thus enabling fabrication of a semiconductor device exhibiting stable characteristics. In a case where the metal layer and the silicon gate can form a plurality of types of metal silicide, a gate electrode of metal silicide having a desired composition is allowed to be formed by appropriately changing the thickness of the first silicon gate formed at the step (a).

The insulating film may include an interlayer insulating film and a sidewall provided on the semiconductor substrate.

A metal capable of forming silicide with silicon, such as Co, Ni or Pt, may be used as a material for the metal film.

A first semiconductor device according to the present invention includes: a semiconductor substrate; an insulating film provided on the semiconductor substrate and having a first recess; a first gate insulating film provided in the first recess on the semiconductor substrate; and a first gate electrode buried in the first recess, provided on the first gate insulating film and made of a metal silicide having a uniform composition.

In a case where the first semiconductor device is a MIS transistor, since the first gate electrode has a uniform silicide composition, electrical characteristics are stabilized, as compared to a conventional semiconductor device including a gate electrode having a nonuniform composition.

A second semiconductor device according to the present invention includes: a semiconductor substrate; an insulating film provided on the semiconductor substrate and having a recess; a gate insulating film provided in the recess on the semiconductor substrate; and a gate electrode buried in the recess, provided on the gate insulating film and made of a metal silicide having a flat upper surface.

In this device, the flatness of the interlayer insulating film formed on the gate electrode is enhanced, and the interlayer insulating film has a uniform thickness.

### BRIEF DESCRIPTION OF THE DRAWINGS

FIGS. 1A through 1E are cross-sectional views showing a method for fabricating a semiconductor device according to a first embodiment of the present invention.

FIGS. 2A through 2E are cross-sectional views showing a method for fabricating a semiconductor device according to a modified example of the first embodiment.

FIGS. 3A through 3H are cross-sectional views showing a method for fabricating a semiconductor device according to a second embodiment of the present invention.

FIGS. 4A through 4C are cross-sectional views showing an example of a flow of conventional FUSI formation.

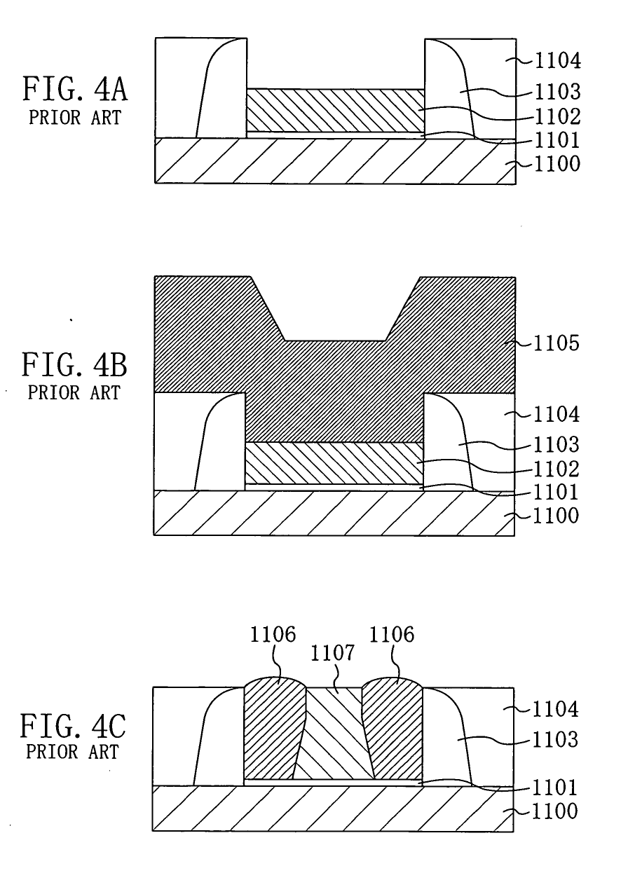

### DETAILED DESCRIPTION OF THE INVENTION

### Embodiment 1

Hereinafter, a method for fabricating a semiconductor device according to a first embodiment of the present invention will be described with reference to the drawings.

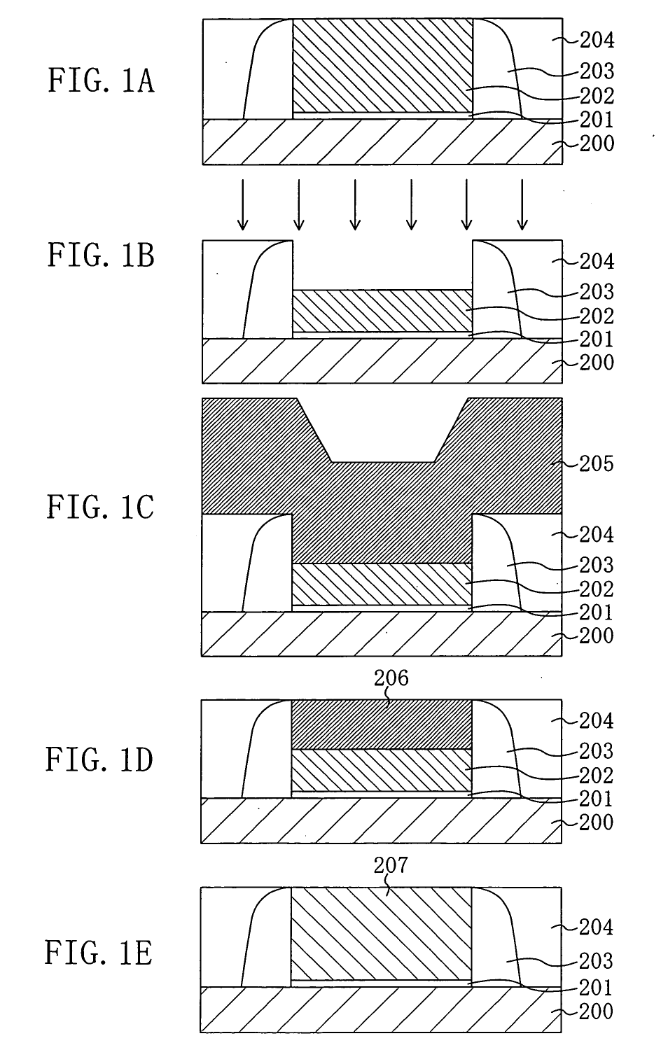

FIGS. 1A through 1E are cross-sectional views showing a method for fabricating a semiconductor device according to the first embodiment.

First, as illustrated in FIG. 1A, a SiON film with a thickness of 2 nm and a polysilicon layer with a thickness of 100 nm are deposited over a semiconductor substrate 200 made of, for example, silicon (Si). Then, the SiON film and the polysilicon layer are partially etched, thereby forming a gate insulating film 201 with a thickness of about 2 nm and a silicon gate 202 with a thickness of 100 nm and a gate length of about 100 nm. Thereafter, extension implantation is performed using the silicon gate 202 as a mask, and then sidewalls 203 made of an insulating film and having a height of 100 nm are formed on side faces of the gate insulating film 201 and the silicon gate 202 by a well-known method. Subsequently, an impurity is implanted in the semiconductor substrate 200 using the silicon gate 202 and the sidewalls 203 as masks, thereby forming source/drain regions (not shown). Then, an interlayer insulating film 204 is deposited. Thereafter, the interlayer insulating film 204 is polished by CMP until the upper surface of the silicon gate 202 is exposed.

Next, as illustrated in FIG. 1B, an upper portion of the silicon gate 202 is selectively removed by, for example, dry etching such that the thickness (height) of the silicon gate 202 is reduced to 50 nm, for example. In this manner, a recess surrounded by the sidewalls 203 is formed on the silicon gate 202. In this process step, wet etching using a chemical solution capable of selectively removing the silicon gate 202 may be performed on the sidewalls 203 and the interlayer insulating film 204.

Then, as illustrated in FIG. 1C, a Ni film 205 is deposited by sputtering to a thickness of 100 nm over the upper surface of the substrate.

Thereafter, as illustrated in FIG. 1D, the Ni film 205 is polished by CMP until the interlayer insulating film 204 is exposed, so that a Ni layer 206 with a thickness of 50 nm having a flat upper surface remains in the recess surrounded by the sidewalls 203 on the silicon gate 202. If the gate length is small, the upper surface of the as-deposited Ni film 205 is substantially flat. In this case, dry etching is used instead of CMP to remove Ni until the upper surface of the interlayer insulating film 204 is exposed, thereby forming a Ni layer 206 having a flat upper surface.

Subsequently, as illustrated in FIG. 1E, heat treatment is performed at 450° C. on the substrate, thereby causing silicidation between the silicon gate 202 and the Ni layer 206. In this manner, a gate electrode 207 having a uniform NiSi phase is formed. The gate electrode 207 having a uniform composition is formed in this process step because Ni is supplied only from a portion directly on top of the silicon gate 202 and the Ni layer 206 has a uniform thickness.

As illustrated in FIG. 1E, the semiconductor device of this embodiment thus fabricated includes: the semiconductor substrate 200; the gate insulating film 201 formed on the semiconductor substrate 200, having a thickness of about 2 nm and made of SiON; the gate electrode 207 formed on the gate insulating film 201, having a flat upper surface and made of Ni silicide, such as NiSi, having a uniform composition; the sidewalls 203 formed on the side faces of the gate electrode 207 and the gate insulating film 201 and made of an insulator; extension regions (not shown) formed in the semiconductor substrate 200 below the sides of the gate electrode 207; source/drain regions (not shown) containing an impurity in a concentration higher than that of the extension regions and formed in the semiconductor substrate 200 below the sides of the gate electrode 207 provided with the sidewalls 203; and the interlayer insulating film 204 formed on the semiconductor substrate 200. The gate electrode 207 has a thickness of, for example, 100 nm and a gate length of, for example, 100 nm.

With the method of this embodiment, the thickness of the Ni layer 206 on the silicon gate 202 is made uniform before the silicidation step shown in FIG. 1E, so that Ni is uniformly supplied to the entire silicon gate 202. This enables fabrication of a semiconductor device including a FUSI gate electrode with a uniform composition. Accordingly, with the method of this embodiment, a miniaturized MIS transistor exhibiting stable characteristics is achieved.

In the method of this embodiment, if the thickness ratio between the silicon gate 202 and the Ni layer 206 formed on the silicon gate 202 is changed, the composition of silicide forming the gate electrode 207 is also arbitrarily selected. In this embodiment, the thickness ratio between the silicon gate 202 and the Ni layer 206 is substantially 1:1 so that the composition of the gate electrode 207 is NiSi.

In the present invention, the thickness of the silicon gate 202 and the thickness of the Ni layer 206 are both 50 nm before silicidation. However, the silicon gate 202 and the Ni layer 206 are not limited to this thickness. It should be noted that the thickness ratio between the silicon gate 202 and the Ni layer 206 is preferably substantially 1:1 in order to form NiSi. Other Ni silicides having desired compositions may be formed by changing the thickness ratio between the silicon gate 202 and the Ni layer 206. For example, the thickness ratio between the silicon gate 202 and the Ni layer 206 may be set at substantially 1:3 to form Ni₃Si, or the thickness ratio between the silicon gate 202 and the Ni layer 206 may be set at substantially 2:1 to form NiSi₂.

In the foregoing description, the Ni layer 206 is formed on the silicon gate 202 to form Ni silicide. Alternatively, a metal layer of, for example, Co or Pt capable of forming silicide with Si may be provided instead of the Ni layer. Metals such as Co can form a plurality of types of silicide having different compositions together with Si. However, the method of this embodiment enables a FUSI gate electrode with a uniform composition to be formed. For example, if Co is used, a FUSI gate electrode of CoSi or CoSi₂ is formed.

In the method of this embodiment, the SiON film is used as the gate insulating film. Alternatively, other insulating films may be used. In such a case, a FUSI gate electrode with a uniform composition is formed in a similar manner.

In the method of this embodiment, polysilicon is used for the silicon gate. Alternatively, amorphous silicon may be used. In such a case, a FUSI gate electrode with a uniform composition is formed in a similar manner.

### Modified Example of Embodiment 1

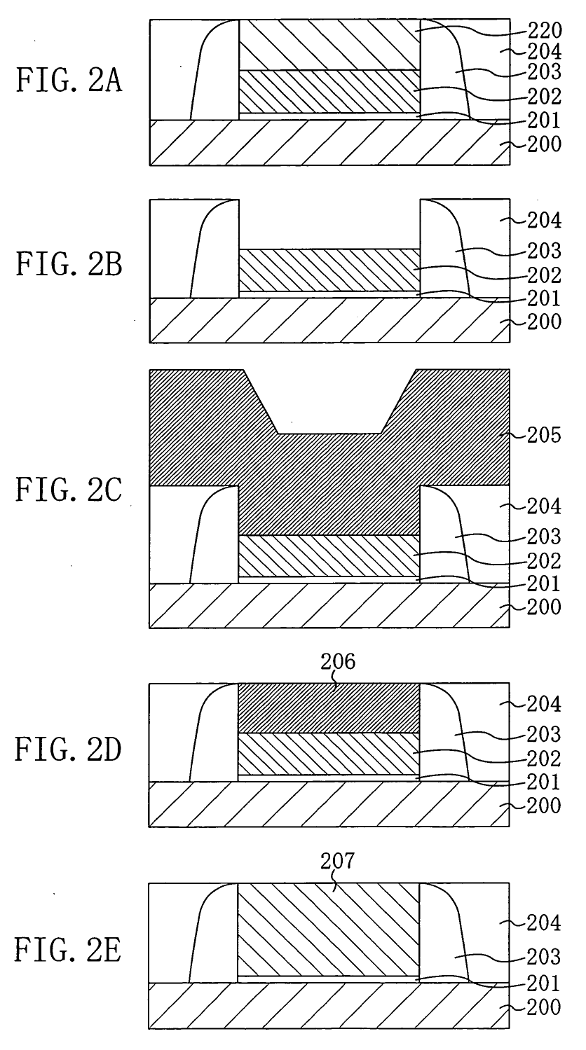

FIGS. 2A through 2E are cross-sectional views showing a method for fabricating a semiconductor device according to a modified example of the first embodiment. This modified example is different from the first embodiment in process steps up to the formation of the silicon gate 202.

First, as illustrated in FIG. 2A, a SiON film with a thickness of 2 nm and a polysilicon layer with a thickness of 50 nm are deposited over a semiconductor substrate 200. Then, a phospho-silicate glass (PSG) layer with a thickness of 50 nm is formed on the polysilicon layer. Thereafter, the PSG layer, the polysilicon layer and the SiON film are partially etched, thereby forming a gate insulating film 201 with a thickness of 2 nm, a silicon gate 202 with a thickness of 50 nm and a protective layer 220 with a thickness of 50 nm, respectively. Subsequently, extension implantation is performed using the silicon gate 202 and the protective layer 220 as masks. Then, sidewalls 203 of an insulating film with a height of 100 nm are formed on side faces of the gate insulating film 201, the silicon gate 202 and the protective layer 220 by a well-known method. Thereafter, an impurity is implanted in the semiconductor substrate 200 using the silicon gate 202, the protective layer 220 and the sidewalls 203 as masks, thereby forming source/drain regions (not shown). Subsequently, an interlayer insulating film 204 is deposited over the substrate. Then, the interlayer insulating film 204 is polished by CMP until the upper surface of the protective layer 220 is exposed.

Next, as illustrated in FIG. 2B, the protective layer 220 on the silicon gate 202 is selectively etched by wet etching using a hydrogen fluoride solution, thereby exposing the upper surface of the silicon gate 202. In this manner, a recess surrounded by the sidewalls 203 is formed on the silicon gate 202.

Thereafter, through the process steps shown in FIGS. 2C through 2E, a semiconductor device of this embodiment is fabricated. These process steps are the same as those shown in FIGS. 1C through 1E, and thus description thereof will be omitted.

The foregoing process steps also allows a semiconductor device including a FUSI gate with a uniform composition to be fabricated. In particular, with the method of this modified example, the height of the silicon gate 202 is adjusted by the deposited thickness, so that the thickness accuracy is enhanced, as compared to the case of adjusting the height by etching. The PSG film used as the protective layer 220 may be replaced by a film having a high etch rate and capable of selectively etching the sidewalls 203, e.g., a BSG, BPSG or ozone-TEOS film, may be used.

### Embodiment 2

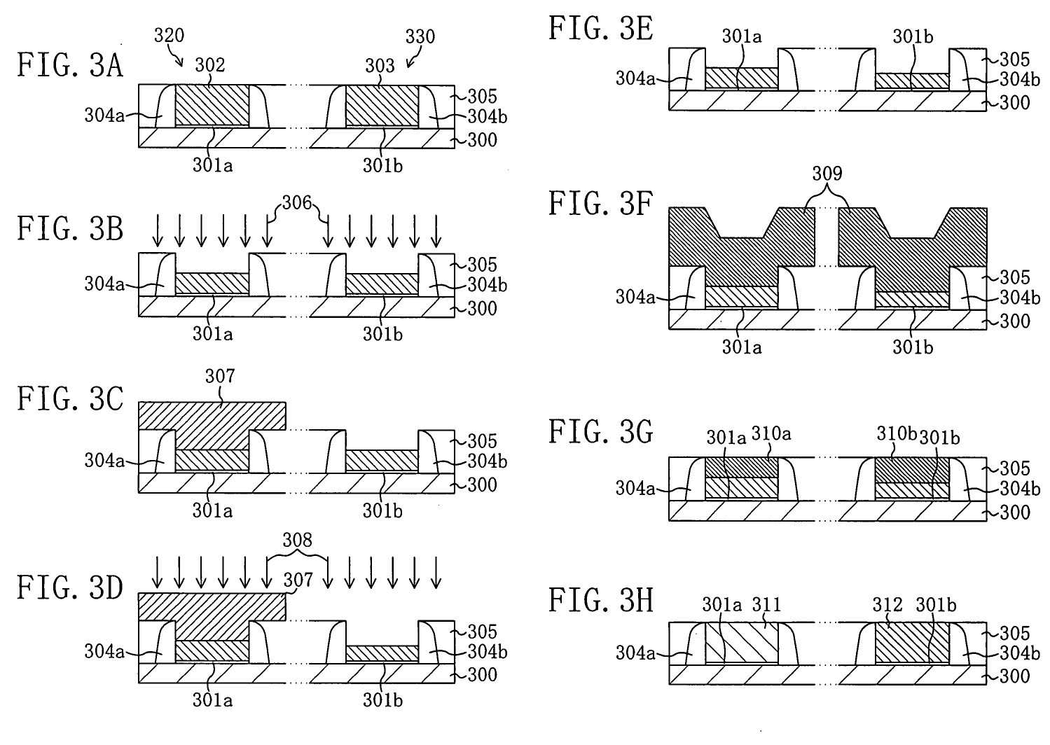

Hereinafter, a method for fabricating a semiconductor device according to a second embodiment of the present invention will be described with reference to the drawings. FIGS. 3A through 3H are cross-sectional views showing a method for fabricating a semiconductor device according to the second embodiment. The method of this embodiment is directed to a method for fabricating a MIS transistor including FUSI gate electrodes having different silicide phases on a wafer. In this embodiment, a NiSi phase is used for a gate electrode of an n-channel MIS (nMIS) transistor and a Ni₃Si phase is used for a gate electrode of a p-channel MIS (pMIS) transistor. In each of FIGS. 3A through 3H, an nMIS region is shown in the left side and a pMIS region is shown in the right side.

First, as illustrated in FIG. 3A, in the same manner as in the first embodiment, a first gate insulating film 301a, a first silicon gate 302 of polysilicon, first sidewalls 304a and source/drain regions (not shown) containing an n-type impurity are formed in an nMIS region 320 of a semiconductor substrate 300, whereas a second gate insulating film 301b, a second silicon gate 303 of polysilicon, second sidewalls 304b and source/drain regions (not shown) containing a p-type impurity are formed in a pMIS region 330 of the semiconductor substrate 300. The first gate insulating film 301a and the second gate insulating film 301b are formed out of an identical film at a time. The first silicon gate 302 and the second silicon gate 303 are formed out of an identical film at a time. The first sidewalls 304a and the second sidewalls 304b are formed out of an identical film at a time. First extension regions containing a low-concentration n-type impurity may be formed below the sides of the first silicon gate 302 in the semiconductor substrate 300. Second extension regions containing a low-concentration p-type impurity may be formed below the sides of the second silicon gate 303 in the semiconductor substrate 300. Thereafter, an insulating film is deposited over the substrate and then is polished by CMP until the upper surfaces of the first silicon gate 302 and the second silicon gate 303 are exposed, thereby forming an interlayer insulating film 305.

The height (thickness) of the first silicon gate 302 and the second silicon gate 303 after this process step is about 100 nm. The height of the first sidewalls 304a and the second sidewalls 304b is approximately equal to that of the silicon gates.

Next, as illustrated in FIG. 3B, upper portions of the first silicon gate 302 and the second silicon gate 303 are selectively subjected to silicon etching 306 using a dry etching technique, thereby reducing the thickness (height) of the first silicon gate 302 and the second silicon gate 303 to 50 nm, for example.

Subsequently, as illustrated in FIG. 3C, a resist 307 having an opening in the pMIS region and covering the nMIS region is formed by lithography.

Thereafter, as illustrated in FIG. 3D, the second silicon gate 303 is subjected to silicon etching 306 using the resist 307 as a mask, thereby reducing the thickness of the second silicon gate 303 to 25 nm. In this process step, the first silicon gate 302 is not etched, so that the thickness of the first silicon gate 302 remains 50 nm. In this manner, a recess surrounded by the sidewalls 304a is formed on the first silicon gate 302, whereas a recess surrounded by the sidewalls 304b is formed on the second silicon gate 303. In this process step, wet etching using a chemical solution capable of selectively removing the sidewalls 304a and 304b and the interlayer insulating film 305 may be performed as a method for etching the first silicon gate 302 and the second silicon gate 303.

Then, as illustrated in FIG. 3E, the resist 307 is removed. Thereafter, as illustrated in FIG. 3F, a Ni film 309 is deposited to a thickness of 100 nm over the upper surface of the substrate including the first silicon gate 302 and the second silicon gate 303.

Thereafter, as illustrated in FIG. 3G, the Ni film 309 is polished by CMP until the upper surface of the interlayer insulating film 305 is exposed, thereby leaving a first Ni layer 310a with a thickness of 50 nm in the recess surrounded by the sidewalls 304a on the first silicon gate 302 and also leaving a second Ni layer 310b with a thickness of 75 nm in the recess surrounded by the sidewalls 304b on the second silicon gate 303. At this time, the upper surfaces of both the first Ni layer 310a and the second Ni layer 310b are planarized, and each of the first Ni layer 310a and the second Ni layer 310b has a uniform thickness. If the gate length is small, the upper surface of the as-deposited Ni film 309 is substantially flat. In this case, dry etching may be used instead of CMP so that Ni is removed until the upper surface of the interlayer insulating film 305 is exposed, thereby forming a first Ni layer 310a and a second Ni layer 310b each having a flat upper surface.

Subsequently, as illustrated in FIG. 3H, the substrate is processed at 450° C. so that silicidation occurs. In this process step, reaction between the first Ni layer 310a and the first silicon gate 302 forms a first gate electrode 311 having a uniform NiSi phase and reaction between the second Ni layer 310b and the second silicon gate 303 forms a second gate electrode 312 having a uniform Ni₃Si phase. At this time, the entire first gate electrode 311 is made of NiSi and the entire second gate electrode 312 is made of Ni₃Si. Through the foregoing process steps, an nMIS transistor and a pMIS transistor each having a uniform silicide phase are formed.

With the method of this embodiment, CMP, for example, is performed after formation of the Ni film 309, so that a Ni layer having a uniform thickness remains only on the silicon gates. Accordingly, a uniform amount of Ni is supplied to each of the entire silicon gates during formation of silicide phases. This allows gate electrodes each having a uniform silicide phase to be formed, and MIS transistors having stable characteristics are fabricated. In addition, if the thickness ratio between each of the silicon gates and its overlying Ni layer is adjusted, FUSI gate electrodes having only desired silicide phases are formed even in a case where a plurality of types of silicide phases can be formed. Accordingly, gate electrodes having different silicide phases are allowed to be formed on a wafer. In the semiconductor device of this embodiment, the gate electrode of NiSi having a preferable work function is formed for the nMIS transistor and the gate electrode of Ni₃Si having a preferable work function is formed for the pMIS transistor. Accordingly, the semiconductor device of this embodiment exhibits higher performance than conventional semiconductor devices.

In the present invention, the first silicon gate 302 has a thickness of 50 nm and the second silicon gate 303 has a thickness of 25 nm before silicidation. However, these gates are not limited to these thicknesses.

In this embodiment, the first gate electrode 311 having a NiSi phase and the second gate electrode 312 having a Ni₃Si phase are formed. However, a gate electrode having any silicide composition may be formed as long as the composition of the gate electrode is uniform.

The first gate electrode 311 having a NiSi phase and the second gate electrode 312 having a Ni₃Si phase may be formed independently of each other or may be directly connected to each other on the isolation region to serve as a dual gate electrode of a CMIS transistor.

In the foregoing description, the gate electrodes of Ni silicides are formed. Alternatively, gate electrodes of silicide containing a metal other than Ni, e.g., Co or Ni, and Si may be formed. Metals such as Co can form a plurality of types of silicide having different compositions together with Si. However, the method of this embodiment allows a FUSI gate electrode with a uniform composition to be formed.

In the method of this embodiment, the first silicon gate 302 and the second silicon gate 303 both having a thickness of 50 nm may be formed through the process step of using a protective layer described in the modified example of the first embodiment.

The state shown in FIG. 3E may be obtained in the following manner. In the process step shown in FIG. 3B, only the second silicon gate 303 is etched by a thickness of 25 nm so that the thickness of the second silicon gate 303 is reduced to 75 nm, using a resist film having an opening in the pMIS region and covering the nMIS region. Thereafter, the resist is removed, and then the entire surface of Ni is etched by a thickness of 50 nm.

As described above, with a method of the present invention, a transistor including a FUSI gate electrode having a uniform silicide phase in a gate electrode plane is allowed to be formed.

What is claimed is:

1. A method for fabricating a semiconductor device, the method comprising the steps of:
(a) forming a first silicon gate over a semiconductor substrate with a first gate insulating film interposed therebetween;
(b) forming a first recess surrounded by an insulating film on the first silicon gate;
(c) forming a metal film over the semiconductor substrate such that at least the first recess is filled with the metal film;
(d) partially removing the metal film to expose the insulating film, thereby forming a first metal layer in the first recess on the first silicon gate; and
(e) performing heat treatment to cause reaction between the first metal layer and the first silicon gate, thereby forming a first gate electrode made of a first metal silicide.

2. The method of claim 1, wherein in the step (b), the insulating film includes an interlayer insulating film provided over the semiconductor substrate and a first sidewall formed on a side face of the first silicon gate, and
the first recess is surrounded by the first sidewall.

3. The method of claim 2, wherein the step (b) includes the steps of:
(b1) forming the first sidewall on the side face of the first silicon gate;
(b2) forming the interlayer insulating film over the entire surface of the semiconductor substrate after the step (b1),
(b3) partially removing the interlayer insulating film to expose an upper surface of the first silicon gate; and
(b4) partially etching the first silicon gate to form the recess after the step (b3).

4. The method of claim 2, wherein the step (a) includes the step of forming a protective layer on the first silicon gate,
the step (b) includes the steps of:
(b1) forming the first sidewall on side faces of the first silicon gate and the protective layer;
(b2) forming the interlayer insulating film over the entire surface of the semiconductor substrate after the step (b1);
(b3) partially removing the interlayer insulating film to expose an upper surface of the protective layer; and
(b4) selectively removing the protective layer to expose an upper surface of the first silicon gate after the step (b3), thereby forming the recess.

5. The method of claim 1, wherein in the step (d), the metal film is removed by chemical mechanical polishing, thereby forming the first metal layer.

6. The method of claim 1, wherein the metal film formed in the step (c) is a Ni film, and
the metal silicide forming the first gate electrode in the step (e) is a material selected from the group consisting of NiSi, NiSi₂ and Ni₃Si.

7. The method of claim 1, wherein the metal film formed in the step (c) is a Co film, and
the metal silicide forming the first gate electrode in the step (e) is a material selected from the group consisting of CoSi and CoSi₂.

8. The method of claim 1, wherein in the step (a), a second silicon gate is formed over the semiconductor substrate with a second gate insulating film interposed therebetween,
in the step (b), a second recess surrounded by the insulating film is formed on the second silicon gate,
in the step (c), the metal film filling the second recess is formed,
in the step (d), the metal film is partially removed so that the insulating film is exposed, thereby forming a second metal layer having a thickness different from that of the first metal layer in the second recess on the second silicon gate, and
in the step (e), the heat treatment is performed to cause reaction between the second metal layer and the second silicon gate, thereby forming a second gate electrode made of a second metal silicide having a composition different from that of the first metal silicide.

9. The method of claim 8, wherein in the step (d), the first silicon gate has a thickness larger than that of the second silicon gate, and
the first metal layer has a thickness smaller than that of the second metal layer.

10. A semiconductor device, comprising:
a semiconductor substrate;
an insulating film provided on the semiconductor substrate and having a first recess;
a first gate insulating film provided in the first recess on the semiconductor substrate; and
a first gate electrode buried in the first recess, provided on the first gate insulating film and made of a metal silicide having a uniform composition.

11. The semiconductor device of claim 10, wherein the insulating film includes: a sidewall provided on a side face of the first gate electrode; and an interlayer insulating film provided on the semiconductor substrate.

12. The semiconductor device of claim 10, wherein the insulating film further has a second recess,
the semiconductor device further comprises:
a second gate insulating film provided in the second recess on the semiconductor substrate; and
a second gate electrode buried in the second recess, provided on the second gate insulating film and made of a metal silicide having a uniform composition different from that of the first gate electrode, and the first gate electrode and the second gate electrode contain an identical metal.

13. The semiconductor device of claim 10, wherein the first gate electrode has a flat upper surface.

14. The semiconductor device of claim 10, wherein the first gate electrode is made of a material selected from the group consisting of Co silicide, Ni silicide and Pt silicide.

15. A semiconductor device, comprising:
a semiconductor substrate;
an insulating film provided on the semiconductor substrate and having a recess;
a gate insulating film provided in the recess on the semiconductor substrate; and
a gate electrode buried in the recess, provided on the gate insulating film and made of a metal silicide having a flat upper surface.
